(19) United States
(12) Patent Application Publication
(10) Pub. No.: US 2025/0112619 A1
(43) Pub. Date: Apr. 3, 2025

(54) ACOUSTIC WAVE DEVICE AND MULTIPLEXER

(71) Applicant: Murata Manufacturing Co., Ltd., Nagaokakyo-shi (JP)

(72) Inventor: Akira NOGUCHI, Nagaokakyo-shi (JP)

(21) Appl. No.: 18/829,753

(22) Filed: Sep. 10, 2024

(30) Foreign Application Priority Data
Sep. 29, 2023 (JP) 2023-169532

(51) Int. Cl. H03H 9/13; H03H 9/17; H03H 9/56; H03H 9/70

(52) U.S. Cl. CPC H03H 9/133; H03H 9/17; H03H 9/568; H03H 9/70

(57) ABSTRACT

A filter includes an acoustic wave resonator including a piezoelectric substrate and an IDT electrode. The piezoelectric substrate includes a piezoelectric layer, a low acoustic velocity layer, and a high acoustic velocity layer. An intersection region of the IDT electrode includes a central region and an edge region. The IDT electrode includes a mass addition film in the edge region. A duty of the IDT electrode and a cut-angle θ° of the piezoelectric layer satisfy any one or more of 0.513≤D≤0.568 and 2.5≤θ≤17.5, 0.538≤D≤0.568 and 17.5≤θ≤22.5, 0.538≤D≤0.588 and 42.5≤θ≤52.5, 0.538≤D≤0.613 and 52.5≤θ≤67.5, 0.513≤D≤0.638 and 67.5≤θ≤77.5, and 0.513≤D≤0.713 and 77.5≤θ≤92.5.

### CROSS REFERENCE TO RELATED APPLICATIONS

This application claims the benefit of priority to Japanese Patent Application No. 2023-169532, filed on Sep. 29, 2023. The entire contents of this application are hereby incorporated herein by reference.

### BACKGROUND OF THE INVENTION

### 1. Field of the Invention

The present invention relates to acoustic wave devices and multiplexers.

### 2. Description of the Related Art

International Publication No. WO 2021/060150 and Japanese Unexamined Patent Application Publication No. 2019-092095 disclose an electrode structure of a surface acoustic wave resonator using a substrate that includes a piezoelectric layer, a low acoustic velocity layer, and a high acoustic velocity layer, and a laminated structure of the substrate. International Publication No. WO 2021/060150 discloses a structure of a piston mode in which a plurality of electrode fingers defining an interdigital transducer (IDT) electrode are partially widened. Japanese Unexamined Patent Application Publication No. 2019-092095 discloses a structure of a piston mode in which a mass addition film is located at a tip of each of a plurality of electrode fingers defining an IDT electrode. With the structures of the piston mode disclosed in International Publication No. WO 2021/060150 and Japanese Unexamined Patent Application Publication No. 2019-092095, it is possible to suppress ripples in a transverse mode.

However, in the acoustic wave resonator having the IDT electrode in the piston mode disclosed in International Publication No. WO 2021/060150 and Japanese Unexamined Patent Application Publication No. 2019-092095, the suppression of unnecessary waves (third harmonic excitation) generated at a frequency three times that of the fundamental wave is insufficient.

### SUMMARY OF THE INVENTION

Example embodiments of the present invention provide acoustic wave devices and multiplexers each including an IDT electrode in a piston mode in which generation of an unnecessary wave of third harmonic excitation is reduced or prevented.

According to an example embodiment of the present invention, an acoustic wave device includes a first acoustic wave resonator including a substrate and an interdigital transducer (IDT) electrode on the substrate. The substrate includes a piezoelectric layer at which the IDT electrode is provided, the piezoelectric layer being made of lithium tantalate, a high acoustic velocity layer in which an acoustic velocity of a bulk wave propagating in the high acoustic velocity layer is higher than an acoustic velocity of an acoustic wave propagating in the piezoelectric layer, and a low acoustic velocity layer in which an acoustic velocity of a bulk wave is lower than an acoustic velocity of a bulk wave propagating in the piezoelectric layer, the low acoustic velocity layer being located between the piezoelectric layer and the high acoustic velocity layer. The IDT electrode includes a plurality of first electrode fingers and a plurality of second electrode fingers that are located in parallel or substantially in parallel with each other, a first busbar electrode connecting single ends of the plurality of first electrode fingers to each other, and a second busbar electrode connecting single ends of the plurality of second electrode fingers to each other, the second busbar electrode opposing the first busbar electrode with the plurality of first electrode fingers and the plurality of second electrode fingers interposed between the second busbar electrode and the first busbar electrode. Where a region in which the plurality of first electrode fingers and the plurality of second electrode fingers overlap each other when viewed from a first direction that is parallel or substantially parallel to the piezoelectric layer and is orthogonal or substantially orthogonal to an extension direction of the first electrode fingers and the second electrode fingers is denoted by an intersection region, the intersection region includes a central region located at a center in the extension direction and an edge region that is located at both outer sides of the central region in the extension direction and has an acoustic velocity lower than an acoustic velocity in the central region. The IDT electrode further includes a mass addition film located in a second direction perpendicular or substantially perpendicular to a main surface of the piezoelectric layer at at least one of the plurality of first electrode fingers and the plurality of second electrode fingers in the edge region. In a case where a duty of the IDT electrode is denoted by D, and a cut-angle of the piezoelectric layer is denoted by θ°, any one or more of the following expressions is satisfied: (1) about 0.513≤D≤ about 0.568 and about 2.5≤θ≤ about 17.5, (2) about 0.538≤D≤ about 0.568 and about 17.5≤θ≤ about 22.5, (3) about 0.538≤D≤ about 0.588 and about 42.5≤θ≤ about 52.5, (4) about 0.538≤D≤ about 0.613 and about 52.5≤θ≤ about 67.5, (5) about 0.513≤D≤ about 0.638 and about 67.5≤θ≤about 77.5, and (6) about 0.513≤D≤ about 0.713 and about 77.5≤θ≤ about 92.5.

According to example embodiments of the present invention, it is possible to provide acoustic wave devices and multiplexers each including an IDT electrode in a piston mode in which generation of unnecessary waves due to third harmonic excitation is reduced or prevented.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a circuit configuration diagram of a multiplexer according to an example embodiment of the present invention.

FIG. 2A is a circuit configuration diagram of an acoustic wave device according to an example embodiment of the present invention.

FIG. 2B is a circuit configuration diagram of an acoustic wave device according to a first modified example of an example embodiment of the present invention.

FIG. 3A is a plan view of a first acoustic wave resonator according to an example embodiment of the present invention.

FIG. 3B is a first cross-sectional view of a first acoustic wave resonator according to an example embodiment of the present invention.

FIG. 3C is a second cross-sectional view of a first acoustic wave resonator according to an example embodiment of the present invention.

FIG. 4A is a plan view of a first acoustic wave resonator according to a second modified example of an example embodiment of the present invention.

FIG. 4B is a cross-sectional view of a first acoustic wave resonator according to the second modified example of an example embodiment of the present invention.

FIG. 5A is a graph illustrating resonance characteristics of an acoustic wave resonator in a case where a duty of the IDT electrode is changed.

FIG. 5B is a graph illustrating a phase of a third harmonic excitation signal of an acoustic wave resonator in a case where the duty of the IDT electrode is changed.

FIG. 5C is a graph illustrating a relationship between the duty of the IDT electrode and the phase of the third harmonic excitation signal.

### DETAILED DESCRIPTION OF THE EXAMPLE EMBODIMENTS

Hereinafter, example embodiments of the present disclosure will be described in detail with reference to the drawings. All of the example embodiments described below describe comprehensive or specific examples. Numerical values, shapes, materials, elements, a disposition and a connection configuration of the elements, and the like illustrated in the following example embodiments are examples and not intended to limit the present invention.

Each drawing is a schematic view in which emphasis, omission, or ratio adjustment is made as appropriate to represent the present invention, and is not necessarily illustrated strictly. In some cases, a shape, a positional relationship, and a ratio may be different from actual ones. In the drawings, the same or substantially the same configurations are denoted by the same reference signs, and repeated description thereof may be omitted or simplified in some cases.

In a circuit configuration of the present disclosure, the phrase “connected between A and B” or “being connected between A and B” means being connected between A and B and being connected to both A and B.

In addition, in a component configuration of the present disclosure, the phrase “a component A is located in series in a path B” means that both a signal input end and a signal output end of the component A are connected to a wire, an electrode, or a terminal defining the path B.

In addition, terms representing a relationship between elements such as “parallel” and “perpendicular”, terms representing a shape of an element such as “rectangular”, and a numerical range not only represent strict meanings, but also mean a substantially equivalent range, for example, that an error of approximately several percent is included.

In addition, in the present disclosure, the term “terminal” means a point where a conductor in an element ends. In a case where an impedance of the conductor between the elements is sufficiently low, the terminal is interpreted as not only a single point but also any point on the conductor between the elements or the entire conductor.

In addition, in the following example embodiments, a pass band of an acoustic wave device or a filter is defined as a frequency band between two frequencies which are about 3 dB higher from a minimum value of an insertion loss in the pass band.

In addition, in the present disclosure, a band A and a band B mean, for example, a frequency band defined in advance by a standardization group or the like (for example, 3GPP (registered trademark) and the Institute of Electrical and Electronics Engineers (IEEE)) for a communication system constructed by using a radio access technology (RAT). In the present example embodiment, as the communication system, for example, a long term evolution (LTE) system, 5th generation (5G)-new radio (NR) system, a wireless local area network (WLAN) system, and the like can be used, but the present invention is not limited thereto.

In addition, an uplink operation band of the band A means a frequency range designated for uplink in the band A. In addition, a downlink operation band of the band A means a frequency range designated for downlink in the band A.

### Example Embodiment

### 1. Circuit Configuration of Multiplexer

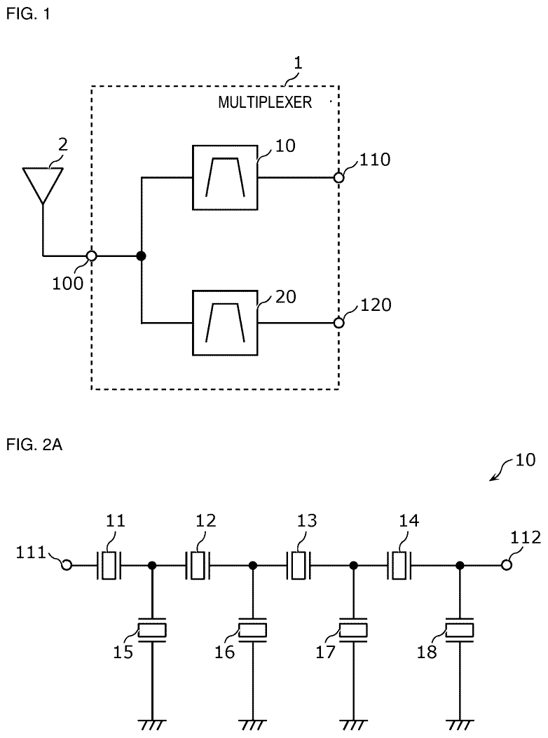

FIG. 1 is a circuit configuration diagram of a multiplexer 1 according to an example embodiment of the present invention. The multiplexer 1 includes filters 10 and 20, a common terminal 100, and input/output terminals 110 and 120.

The common terminal 100 is connected to, for example, an antenna 2.

The filter 10 is an example of an acoustic wave device and includes a first acoustic wave resonator. The filter 10 is connected to the common terminal 100, and has a pass band including an uplink operation band of a band A, for example. The filter 20 is connected to the common terminal 100 and has a pass band including a downlink operation band of the band A, for example. The filters 10 and 20 define, for example, a duplexer for the band A.

The filter 10 may have a pass band including at least one of the uplink operation band and the downlink operation band of the band A, and the filter 20 may have a pass band including at least one of the uplink operation band and the downlink operation band of a band B different from the band A. In this case, the filters 10 and 20 define a diplexer.

In the present example embodiment, the pass band of the filter 10 is located on a low frequency side as compared with the pass band of the filter 20. At least one of a plurality of acoustic wave resonators defining filter 10 can reduce unnecessary waves of the third harmonic excitation. Thus, even though the unnecessary waves of the third harmonic excitation generated by the filter 10 are included in the vicinity of the pass band of the filter 20, it is possible to reduce or prevent the deterioration in the bandpass characteristic of the filter 20.

The pass band of the filter 10 may be located on a higher frequency side than the pass band of the filter 20.

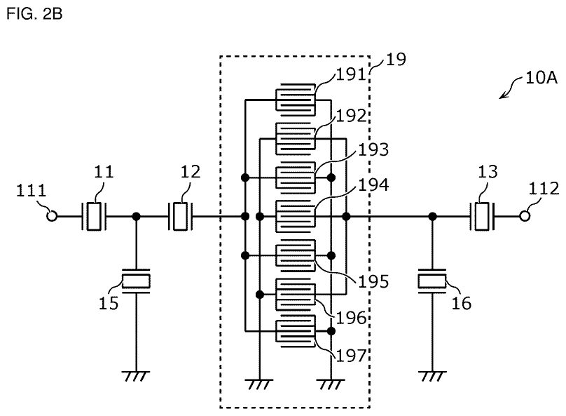

FIG. 2A is a circuit configuration diagram of the filter 10 according to the present example embodiment. As illustrated in FIG. 2A, the filter 10 includes series arm resonators 11, 12, 13, and 14, parallel arm resonators 15, 16, 17, and 18, and terminals 111 and 112.

The terminal 111 is an example of a first input/output terminal and is connected to the common terminal 100. The terminal 112 is an example of a second input/output terminal and is connected to the input/output terminal 110.

Each of the series arm resonators 11 to 14 is an acoustic wave resonator and is located in series in a path connecting the terminal 111 and the terminal 112. The series arm resonator 11 is an example of the first acoustic wave resonator and is connected closest to the common terminal 100 among the series arm resonators 11 to 14 and the parallel arm resonators 15 to 18.

The parallel arm resonator 15 is an acoustic wave resonator and is connected between a node of the series arm resonators 11 and 12 and the ground. The parallel arm resonator 16 is an acoustic wave resonator and is connected between a node of the series arm resonators 12 and 13 and the ground. The parallel arm resonator 17 is an acoustic wave resonator and is connected between a node of the series arm resonators 13 and 14 and the ground. The parallel arm resonator 18 is an acoustic wave resonator and is connected between a node of the series arm resonator 14 and the terminal 112, and the ground.

With the above-described configuration, the filter 10 defines, for example, a ladder band pass filter. Each of the series arm resonators 11 to 14 and the parallel arm resonators 15 to 18 includes an IDT electrode located at a substrate having piezoelectricity.

The circuit configuration of the filter 10 illustrated in FIG. 2A is an example, and the number of series arm resonators and the number of parallel arm resonators are not limited to four each, and it is sufficient that the number of series arm resonators and the number of parallel arm resonators be each one or more. In addition, an inductor may be connected between the parallel arm resonator and the ground.

In addition, the filter 10 is not limited to a ladder band pass filter, and may be, for example, a filter including a longitudinally coupled resonator in which a plurality of acoustic wave resonators are juxtaposed in an acoustic wave propagation direction, as illustrated in FIG. 2B.

FIG. 2B is a circuit configuration diagram of a filter 10A according to a first modified example of the present example embodiment. The filter 10A is an example of an acoustic wave device and is connected to a common terminal 100. As illustrated in FIG. 2B, the filter 10A is a filter circuit preferably including a longitudinally coupled resonator 19 including seven acoustic wave resonators, and includes the longitudinally coupled resonator 19, series arm resonators 11, 12, and 13, parallel arm resonators 15 and 16, and terminals 111 and 112. The terminal 111 is connected to the common terminal 100, and the terminal 112 is connected to an input/output terminal 120.

The longitudinally coupled resonator 19 includes acoustic wave resonators 191, 192, 193, 194, 195, 196, and 197. One end of the longitudinally coupled resonator 19 is connected to the terminal 111 through the series arm resonators 11 and 12, and the other end of the longitudinally coupled resonator 19 is connected to the terminal 112 through the series arm resonator 13.

Each of the acoustic wave resonators 191 to 197 includes an IDT electrode located at a substrate having piezoelectricity. Each of the IDT electrodes of the acoustic wave resonators 191 to 197 includes two comb electrodes opposing each other. One comb electrode of each of the acoustic wave resonators 191, 193, 195, and 197 is connected to the terminal 111 through the series arm resonators 11 and 12, and the other comb electrode of each of the acoustic wave resonators 191, 193, 195, and 197 is connected to the ground. One comb electrode of each of the acoustic wave resonators 192, 194, and 196 is connected to the terminal 112 through the series arm resonator 13, and the other comb electrode of each of the acoustic wave resonators 192, 194, and 196 is connected to the ground. The acoustic wave resonators 191 to 197 are located along the acoustic wave propagation direction in order of the acoustic wave resonators 191, 192, 193, 194, 195, 196, and 197.

The series arm resonators 11, 12, and 13 are located in series in a path connecting the terminals 111 and 112. Each of the parallel arm resonators 15 and 16 is connected between the path and the ground. The series arm resonator 11 is an example of the first acoustic wave resonator and is connected closest to the common terminal 100 among the series arm resonators 11 to 13, the longitudinally coupled resonator 19, and the parallel arm resonators 15 and 16.

The filter 20 may be any of a band pass filter, a notch filter, a low pass filter, or a high pass filter, and includes at least one of an acoustic wave resonator, an inductor, and a capacitor, for example.

In a case where the filter 20 includes an acoustic wave resonator, the filters 10 and 20 may be provided at the same piezoelectric substrate. Accordingly, it is possible to reduce the size of the multiplexer 1 and to simplify the manufacturing process. In addition, in a case where the filter 20 includes the acoustic wave resonator, the film thickness of the IDT electrode of the acoustic wave resonator may be the same or substantially the same as the film thickness of the IDT electrode of the acoustic wave resonator defining the filter 10. Accordingly, it is possible to simplify the manufacturing process of the multiplexer 1.

### 2. Structure of First Acoustic Wave Resonator

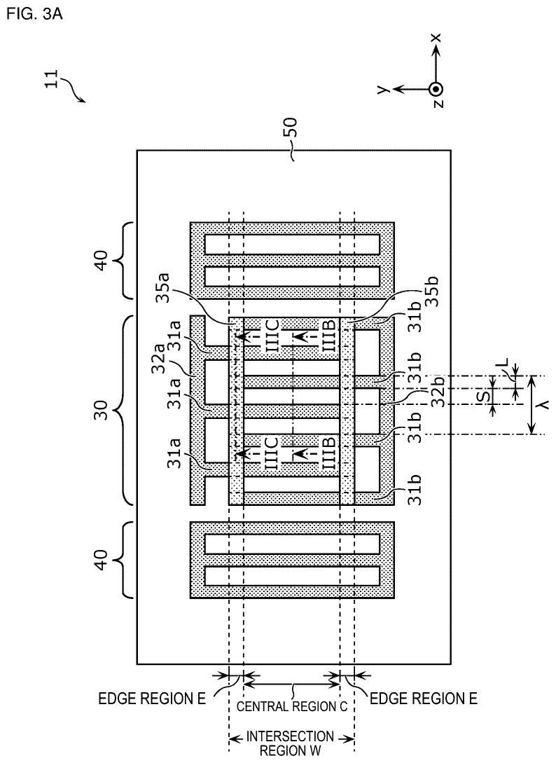

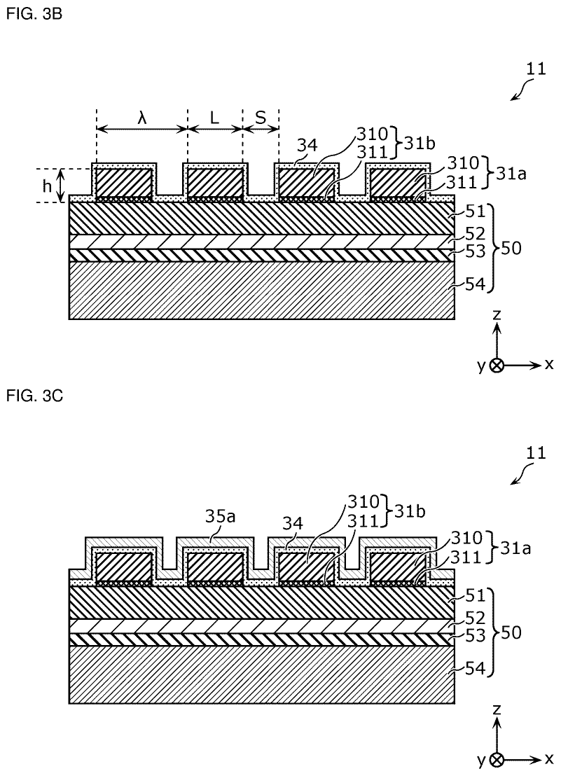

Next, a structure of the first acoustic wave resonator defining the filter 10 will be described. FIG. 3A is a plan view of the series arm resonator 11 according to the present example embodiment. FIG. 3B is a first cross-sectional view of the series arm resonator 11 according to the present example embodiment. FIG. 3C is a second cross-sectional view of the series arm resonator 11 according to the present example embodiment. The series arm resonator 11 illustrated in FIGS. 3A to 3C is an example of the first acoustic wave resonator. FIG. 3B illustrates a cross-sectional view taken along line IIIB-IIIB of FIG. 3A, and FIG. 3C illustrates a cross-sectional view taken along line IIIC-IIIC of FIG. 3A.

As illustrated in FIGS. 3A to 3C, the series arm resonator 11 includes a piezoelectric substrate 50, an IDT electrode 30, and a reflective electrode 40. The series arm resonator 11 illustrated in FIGS. 3A to 3C is provided to describe a typical structure of the first acoustic wave resonator defining the filter 10, and the number, the length, and the like of electrode fingers defining the IDT electrode 30 are not limited thereto. The IDT electrode 30 and the reflective electrode 40 are located on the piezoelectric substrate 50 (in the positive z-axis direction).

As illustrated in FIGS. 3B and 3C, the piezoelectric substrate 50 has piezoelectricity and includes a piezoelectric layer 51, a low acoustic velocity layer 52, a high acoustic velocity layer 53, and a support substrate 54.

The IDT electrode 30 and the reflective electrode 40 are located on one surface of the piezoelectric layer 51. As the piezoelectric layer 51, for example, a material having lithium tantalate (LiTaO₃) or lithium tantalate as the main component can be used. The film thickness of the piezoelectric layer 51 is about 900 nm, for example.

The high acoustic velocity layer 53 is located on the other surface side of the piezoelectric layer 51, and an acoustic velocity of a bulk wave propagating in the high acoustic velocity layer 53 is higher than an acoustic velocity of an acoustic wave propagating in the piezoelectric layer 51. As a material of the high acoustic velocity layer 53, for example, a piezoelectric body such as aluminum nitride, lithium tantalate, lithium niobate, and crystal, ceramic such as alumina, sapphire, magnesia, silicon nitride, silicon carbide, zirconia, cordierite, mullite, steatite, forsterite, a dielectric such as diamond and glass, a semiconductor such as silicon and gallium nitride, or a resin, and alternatively, a material having the above-described materials as the main components can be used. The film thickness of the high acoustic velocity layer 53 is about 300 nm, for example.

The low acoustic velocity layer 52 is located between the other main surface of the piezoelectric layer 51 and one main surface of the high acoustic velocity layer 53, and the acoustic velocity of the bulk wave propagating in the low acoustic velocity layer 52 is lower than that of the bulk wave propagating in the piezoelectric layer 51. With the structure and the properties that energy of an acoustic wave is essentially concentrated on a medium having a low acoustic velocity, a leakage of surface acoustic wave energy out from the piezoelectric layer 51 is reduced or prevented. As the low acoustic velocity layer 52, for example, a dielectric body such as silicon oxide, glass, silicon oxynitride, lithium oxide, tantalum oxide, and a compound obtained by adding fluorine, carbon, or boron to silicon oxide, or a material having the above-described material as the main component can be used. The film thickness of the low acoustic velocity layer 52 is about 300 nm, for example.

The support substrate 54 is located on the other main surface of the high acoustic velocity layer 53, and supports the IDT electrode 30, the piezoelectric layer 51, the low acoustic velocity layer 52, and the high acoustic velocity layer 53. As a material of the support substrate 54, for example, a piezoelectric body such as aluminum nitride, lithium tantalate, lithium niobate, and crystal, ceramic such as alumina, sapphire, magnesia, silicon nitride, silicon carbide, zirconia, cordierite, mullite, steatite, forsterite, a dielectric such as diamond and glass, a semiconductor such as silicon and gallium nitride, or a resin, and alternatively, a material having the above-described materials as the main components can be used. The thickness of the support substrate 54 is preferably, for example, about 125 μm.

According to the above-described laminated structure of the piezoelectric substrate 50, a Q value in a resonant frequency and an anti-resonant frequency can be significantly increased, compared to a structure in the related art in which the single-layer piezoelectric substrate is used. That is, since the acoustic wave resonator having a great Q value can be configured, a radio frequency filter having a small insertion loss can be configured by using the acoustic wave resonator.

The piezoelectric layer 51 may be directly located on the high acoustic velocity layer 53 without providing the low acoustic velocity layer 52, if so desired.

The high acoustic velocity layer 53 and the support substrate 54 may alternatively be combined as one high acoustic velocity support substrate. The high acoustic velocity support substrate supports the IDT electrode 30, the piezoelectric layer 51, and the low acoustic velocity layer 52. In the high acoustic velocity support substrate, the acoustic velocity of a bulk wave in the high acoustic velocity support substrate is higher than the acoustic velocity of an acoustic wave such as a surface acoustic wave or a boundary acoustic wave propagating in the piezoelectric layer 51. The high acoustic velocity support substrate functions to confine the surface acoustic wave in a portion in which the piezoelectric layer 51 and the low acoustic velocity layer 52 are laminated, and prevent the downward leakage from the high acoustic velocity support substrate. As a material of the high acoustic velocity support substrate, for example, a piezoelectric body such as aluminum nitride, lithium tantalate, lithium niobate, and crystal, ceramic such as alumina, sapphire, magnesia, silicon nitride, silicon carbide, zirconia, cordierite, mullite, steatite, forsterite, spinel, and sialon, a dielectric such as aluminum oxide, silicon oxynitride, diamond-like carbon (DLC), and diamond, or a semiconductor such as silicon, and alternatively, a material that includes the above-described materials as the main components can be used. The above-described spinel includes an aluminum compound including one or more elements selected from Mg, Fe, Zn, and Mn, oxygen, and the like. Examples of the above-described spinel can include MgAl₂O₄, FeAl₂O₄, ZnAl₂O₄, and MnAl₂O₄.

In the present specification, the phrase “main component of the material” means a component in which a ratio occupied by the material exceeds 50% by weight. The main component may exist in any one state of single crystal, polycrystal, and amorphous, or in a mixed state thereof.

In addition, instead of the piezoelectric substrate 50, a structure in which a support substrate, an energy confinement layer, and a piezoelectric layer are laminated in this order may be provided. The IDT electrode 30 and the reflective electrode 40 are provided on the piezoelectric layer. As the piezoelectric layer, for example, the LiTaO₃ piezoelectric single crystal or the piezoelectric ceramics is used. The support substrate supports the piezoelectric layer, the energy confinement layer, and the IDT electrode 30.

The energy confinement layer includes one layer or a plurality of layers, and the velocity of the bulk acoustic wave propagating in the at least one layer is higher than the velocity of the acoustic wave propagating in the vicinity of the piezoelectric layer. For example, the energy confinement layer may have a laminated structure of a low acoustic velocity layer and a high acoustic velocity layer. The low acoustic velocity layer is a film in which the acoustic velocity of the bulk wave in the low acoustic velocity layer is lower than the acoustic velocity of the acoustic wave propagating in the piezoelectric layer. The high acoustic velocity layer is a film in which the acoustic velocity of the bulk wave in the high acoustic velocity layer is higher than the acoustic velocity of the acoustic wave propagating in the piezoelectric layer. The support substrate may be a high acoustic velocity layer.

In addition, the energy confinement layer may be an acoustic impedance layer having a configuration in which a low acoustic impedance layer having a relatively low acoustic impedance and a high acoustic impedance layer having a relatively high acoustic impedance are alternately laminated.

As illustrated in FIG. 3A, the IDT electrode 30 includes a plurality of electrode fingers 31a and a plurality of electrode fingers 31b, busbar electrodes 32a and 32b, and mass addition films 35a and 35b.

Each of the plurality of electrode fingers 31a and the plurality of electrode fingers 31b extends in a direction perpendicular or substantially perpendicular to the acoustic wave propagation direction (x-axis direction: first direction), and the plurality of electrode fingers 31a and the plurality of electrode fingers 31b are located parallel or substantially parallel to each other. The electrode finger 31a is an example of a first electrode finger, and the electrode finger 31b is an example of a second electrode finger.

The busbar electrode 32a is an example of a first busbar electrode, and is configured to connect single ends of the plurality of electrode fingers 31a to each other. The busbar electrode 32a extends in a direction (x-axis direction) intersecting with an extension direction (y-axis direction) of the plurality of electrode fingers 31a. The busbar electrode 32b is an example of a second busbar electrode, and is configured to connect single ends of the plurality of electrode fingers 31b to each other. The busbar electrode 32b extends in the direction (x-axis direction: first direction) intersecting with the extension direction (y-axis direction) of the plurality of electrode fingers 31b. The busbar electrodes 32a and 32b are located to oppose each other with a plurality of electrode fingers 31a and a plurality of electrode fingers 31b interposed between the busbar electrodes 32a and 32b. The other end of the plurality of electrode fingers 31a opposes the busbar electrode 32b, and the other end of the plurality of electrode fingers 31b opposes the busbar electrode 32a. The busbar electrodes 32a and 32b may extend in a direction that intersects with the extension direction (y-axis direction) and is not orthogonal to the extension direction (y-axis direction).

The reflective electrode 40 is located on both sides of the IDT electrode 30 to be adjacent to the IDT electrode 30 in the direction (x-axis direction) perpendicular or substantially perpendicular to the extension direction of the plurality of electrode fingers 31a and the plurality of electrode fingers 31b. The reflective electrode 40 is configured to confine a predetermined radio frequency signal resonating in the IDT electrode 30 into the IDT electrode 30. The reflective electrode 40 includes a plurality of electrode fingers and a pair of busbar electrodes. The plurality of electrode fingers of the reflective electrode 40 are located in parallel or substantially in parallel with the plurality of electrode fingers 31a and 31b. One of the busbar electrodes of the reflective electrode 40 is configured to connect single ends of the plurality of electrode fingers of the reflective electrode 40 to each other, and the other busbar electrode of the reflective electrode 40 is configured to connect the other ends of the plurality of electrode fingers of the reflective electrode 40 to each other. In the series arm resonator 11 according to the present example embodiment, the reflective electrode 40 does not need to be provided.

As illustrated in FIGS. 3B and 3C, the plurality of electrode fingers 31a and 31b, the busbar electrodes 32a and 32b, and the reflective electrode 40 have, for example, a laminated structure of a close contact layer 311 and a main electrode layer 310.

For example, the main electrode layer 310 preferably includes aluminum (Al) as the main component, and the film thickness is preferably about 320 nm, for example. The close contact layer 311 is located between the main electrode layer 310 and the piezoelectric layer 51, and is configured to improve a close contact degree of the main electrode layer 310 to the piezoelectric layer 51. For example, the close contact layer 311 is preferably made of titanium (Ti), and the film thickness is about 30 nm, for example. In addition, the plurality of electrode fingers 31a and 31b, the busbar electrodes 32a and 32b, and the reflective electrode 40 are not limited to the above-described laminated structure and may be configured of, for example, metal such as Ti, Al, Cu, Pt, Au, Ag, or Pd or alloys, or may be configured by a plurality of multilayer bodies configured of the above-described metal or alloys.

In addition, as illustrated in FIGS. 3B and 3C, a protection layer 34 is located to cover the plurality of electrode fingers 31a and 31b and the busbar electrodes 32a and 32b. The protection layer 34 is a layer to protect the main electrode layer 310 from the outside environment, for adjusting frequency-temperature characteristics, and for improving humidity resistance, and the like. The protection layer 34 is, for example, a dielectric film containing silicon oxide as the main component. The protection layer 34 does not need to be provided if so desired.

Here, as illustrated in FIG. 3A, the main surface of the piezoelectric substrate 50 is divided into a plurality of regions. A region where the plurality of electrode fingers 31a and the plurality of electrode fingers 31b overlap each other when viewed from a first direction (x-axis direction) that is parallel to the main surface of the piezoelectric layer 51 and is orthogonal to the extension direction of the electrode fingers 31a and 31b is denoted by an intersection region W. The intersection region W has a central region C and an edge region E. The central region C is located at the center in the extension direction (y-axis direction). The edge region E is located at both outer sides of the central region C in the extension direction (y-axis direction) and has an acoustic velocity lower than an acoustic velocity in the central region C.

Each of the mass addition films 35a and 35b is located along the x-axis direction in a second direction (z-axis direction) perpendicular to the main surface of the piezoelectric layer 51 in a region of the plurality of electrode fingers 31a and 31b and a region between the electrode fingers 31a and 31b in the edge region E. Since the mass addition films 35a and 35b are located, the edge region E has an acoustic velocity lower than the central region C.

From the above description, the central region C is defined as a region sandwiched between the mass addition films 35a and 35b of the IDT electrode 30, where the mass addition films 35a and 35b are not located. The length of the central region C in the extension direction (y-axis direction) is optional. The edge region E is defined as a region located at both outer sides of the central region C in the extension direction (y-axis direction), where the mass addition film 35a or 35b is located.

As a structure to make the acoustic velocity of the edge region E lower than the acoustic velocity of the central region C, the mass addition film 35a or 35b is located in the edge region E in addition to the structure of the central region C.

Examples of the mass addition films 35a and 35b to make the edge region E as a region where the acoustic velocity is lower than the acoustic velocity in the central region C include a dielectric film including any one of tantalum oxide (Ta₂O₅), titanium oxide (TiO₂), hafnium oxide (HfO₂), niobium oxide (Nb₂O₅), tungsten oxide (WO₃), cerium oxide (CeO₂), and silicon oxide (SiO₂) as a main component, and a metal film.

The mass addition films 35a and 35b do not need to be located in the region between the electrode finger 31a and the electrode finger 31b in the edge region E. The mass addition film 35a may be located only at the electrode finger 31b in the edge region E, and the mass addition film 35b may be located only at the electrode finger 31a in the edge region E.

Here, electrode parameters of the IDT electrode defining the acoustic wave resonator will be described.

The wavelength of the acoustic wave resonator is defined by a wavelength λ that is the repeating period of the plurality of electrode fingers 31a or 31b illustrated in FIGS. 3A and 3B. In other words, the wavelength λ is about twice an electrode finger pitch that is a distance between the center of the electrode finger 31a and the center of the electrode finger 31b, the electrode finger 31a and the electrode finger 31b being adjacent to each other. The electrode finger pitch is defined by (L+S) in a case where the line width of the electrode fingers 31a and 31b is denoted by L and a space width between the adjacent electrode finger 31a and electrode finger 31b is denoted by S. In addition, the duty D of the IDT electrode 30 is a line width occupancy ratio of the plurality of electrode fingers 31a and 31b, is a ratio of the line width with respect to the sum of the line width of the plurality of electrode fingers 31a and 31b and the space width, and is defined as L/(L+S). In FIG. 3B, the height of the electrode fingers 31a and 31b is denoted by h.

In the IDT electrode 30, in a case where an interval between the electrode fingers adjacent to each other is not constant, the electrode finger pitch of the IDT electrode 30 is defined as an average electrode finger pitch of the IDT electrode 30. The average electrode finger pitch of the IDT electrode 30 is defined as Di/(Ni−1), when the total number of the electrode fingers 31a and 31b included in the IDT electrode 30 is denoted by Ni, and an inter-center distance between the electrode finger located in one end of the IDT electrode 30 and the electrode finger located in the other end in the acoustic wave propagation direction (x-axis direction) is denoted by Di.

In addition, in a case where the duties of the electrode fingers 31a and 31b are not uniform, the duty D of the IDT electrode 30 is defined by averaging the duties of the plurality of electrode fingers 31a and the plurality of electrode fingers 31b.

The IDT electrode 30 of the series arm resonator 11 according to the present example embodiment has a structure of a 3D piston mode in which the mass addition film is located in the second direction of the electrode finger, and thus it is possible to reduce or prevent ripples in a transverse mode.

Further, the IDT electrode 30 of the series arm resonator 11 according to the present example embodiment is suitable for increasing the duty of the IDT electrode 30 with high accuracy as compared with an IDT electrode having a 2D piston structure in which the width of a portion of the electrode finger is widened in the first direction.

### 3. Structure of First Acoustic Wave Resonator According to Second Modified Example

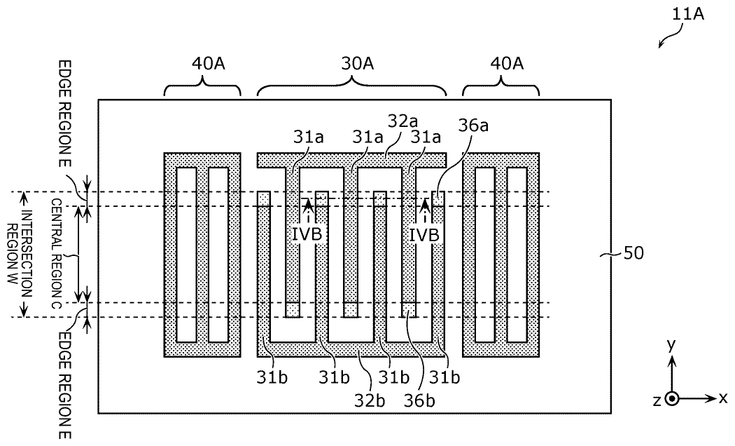

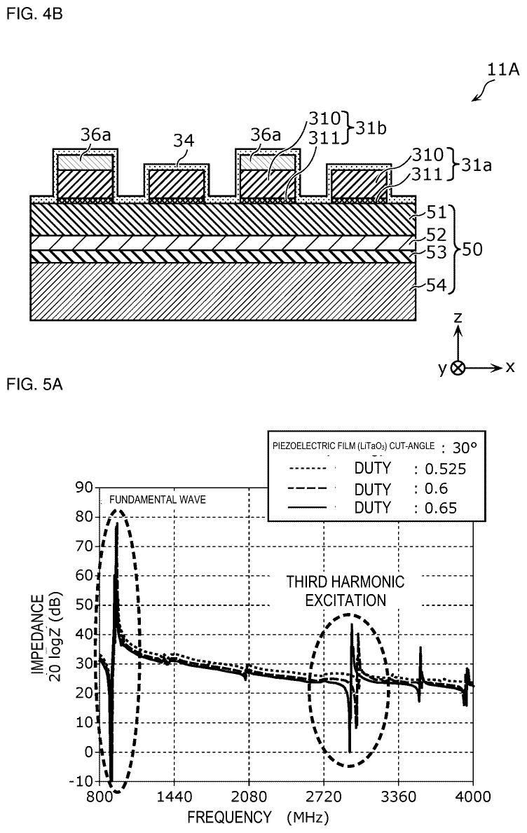

Next, the structure of a first acoustic wave resonator defining a filter 10 according to a second modified example will be described. FIG. 4A is a plan view of a series arm resonator 11A according to the second modified example of the present example embodiment. FIG. 4B is a cross-sectional view of the series arm resonator 11A according to the second modified example of the present example embodiment. FIG. 4B illustrates a cross-sectional view taken along line IVB-IVB of FIG. 4A.

The filter 10 according to the second modified example preferably has a circuit configuration in which the series arm resonator 11 in the circuit illustrated in FIG. 2A is replaced with the series arm resonator 11A. The series arm resonator 11A illustrated in FIGS. 4A and 4B is an example of the first acoustic wave resonator.

As illustrated in FIGS. 4A and 4B, the series arm resonator 11A includes a piezoelectric substrate 50, an IDT electrode 30A, and a reflective electrode 40A. The series arm resonator 11A illustrated in FIGS. 4A and 4B is provided to describe a typical structure of the first acoustic wave resonator defining the filter 10 according to the second modified example, and the number, the length, and the like of electrode fingers defining the IDT electrode 30A are not limited thereto. The IDT electrode 30A and the reflective electrode 40A are located on the piezoelectric substrate 50 (in the positive z-axis direction). The series arm resonator 11A according to the present modified example differs from the series arm resonator 11 according to the example embodiment only in the configurations of mass addition films 36a and 36b. The series arm resonator 11A according to the present modified example will be described focusing on the different configurations without describing the same or substantially the same configurations as the series arm resonator 11 according to the example embodiment.

As illustrated in FIG. 4A, the IDT electrode 30A includes a plurality of electrode fingers 31a and a plurality of electrode fingers 31b, busbar electrodes 32a and 32b, and mass addition films 36a and 36b.

Each of the mass addition films 36a and 36b is located in the second direction (z-axis direction) perpendicular or substantially perpendicular to the main surface of the piezoelectric layer 51 at the tip end portions of the plurality of electrode fingers 31a and 31b in the edge region E. The mass addition films 36a and 36b are not located in the region between the electrode finger 31a and the electrode finger 31b in the edge region E.

Since the mass addition films 36a and 36b are provided, the edge region E has an acoustic velocity lower than the central region C.

The mass addition films 36a and 36b are preferably made of, for example, the same conductive material as the plurality of electrode fingers 31a and the plurality of electrode fingers 31b.

The mass addition film 36a may be further located at the electrode finger 31a in the edge region E, and the mass addition film 36b may be further located at the electrode finger 31b in the edge region E.

The IDT electrode 30A of the series arm resonator 11A according to the present modified example has a structure of a 3D piston mode in which the mass addition film is located in the second direction of the electrode finger, and thus it is possible to reduce or prevent ripple in a transverse mode.

Further, the IDT electrode 30A of the series arm resonator 11A according to the present modified example is suitable to increase the duty of the IDT electrode 30A with high accuracy as compared with an IDT electrode having a so-called 2D piston structure in which the width of a portion of the electrode finger is widened in the first direction.

### 4. Relationship Between Cut-Angle of Piezoelectric Layer and Duty of IDT Electrode

Next, the cut-angle θ of the piezoelectric layer and the duty D of the IDT electrode to reduce or prevent a third harmonic excitation response of the first acoustic wave resonator having the structure of the 3D piston mode will be described. For example, the piezoelectric layer 51 (LiTaO₃) is a θ° Y-cut X propagation LiTaO₃ piezoelectric single crystal or piezoelectric ceramics (single crystal or ceramics through which the surface acoustic wave propagates in an X-axis direction, which is lithium tantalate single crystal or ceramics cut by a plane in which the X-axis is set as a central axis, and an axis rotated by θ° from the Y-axis is set as a normal line). The cut-angle θ described below is θ of the θ° Y-cut X propagation LiTaO₃.

Table 1 shows an example of parameters of an acoustic wave resonator having the structure of the 3D piston mode.

TABLE 1

| Acoustic Wave Resonator | | |
|---|---|---|
| IDT Electrode | Electrode Finger | 4.25 |
| | Wavelength λ (μm) | |
| | Electrode Finger Film | Main Electrode |
| | Thickness (nm) | Layer: 320 |
| | | Close Contact |
| | | Layer: 30 |
| | Intersection Width (λ) | 10 |
| | Number Of Pairs (pairs) | 100 |
| | IR-Gap (λ) | 0.5 |
| Piezoelectric | Piezoelectric Layer | 900 |
| Substrate | (LiTaO₃) (nm) | |
| | Low Acoustic Velocity | 300 |
| | Layer (SiO₂) (nm) | |
| | High Acoustic Velocity | 300 |
| | Layer (SiN) (nm) | |
| | Support Substrate (Si) | 125 |
| | (μm) | |

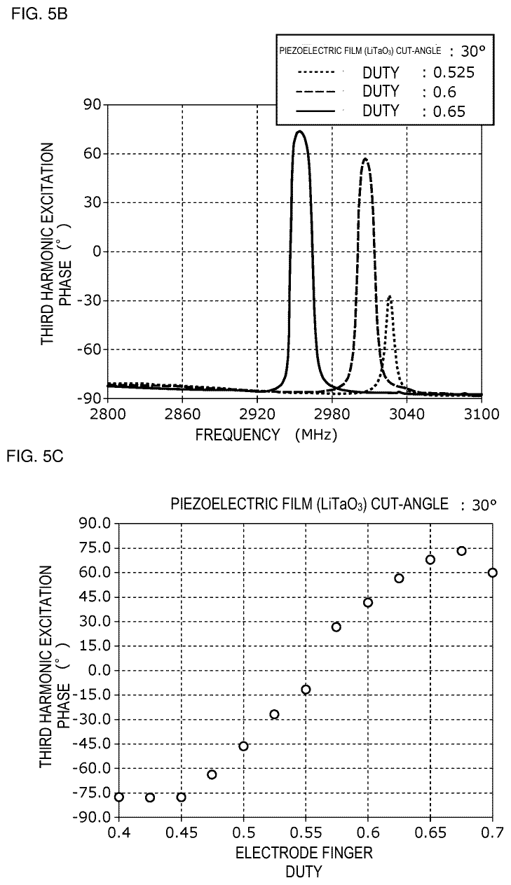

FIG. 5A is a graph illustrating resonance characteristics of an acoustic wave resonator in a case where the duty of the IDT electrode is changed. FIG. 5B is a graph illustrating a phase of a third harmonic excitation signal of the acoustic wave resonator in a case where the duty of the IDT electrode is changed. FIG. 5C is a graph illustrating a relationship between the duty of the IDT electrode and the phase of the third harmonic excitation signal.

Acoustic wave resonators having characteristics illustrated in FIGS. 5A to 5C have the parameters shown in Table 1 and have the structure of the 3D piston mode illustrated in FIGS. 3A to 3C.

As illustrated in FIGS. 5A and 5B, in a case where the duty D is changed to about 0.525, about 0.6, and about 0.65 at the cut-angle θ=about 30° of a piezoelectric layer that is generally used, the resonance characteristics of the fundamental wave do not substantially change, but the intensity (the difference in impedance between the resonant frequency and the anti-resonant frequency) and the phase of the third harmonic excitation increase as the duty increases. It is illustrated that the larger the phase of the third harmonic excitation signal (close to +90°), the higher the intensity of the third harmonic excitation signal, and the smaller the phase of the third harmonic excitation signal (close to −90°), the lower the intensity of the third harmonic excitation signal.

In addition, as illustrated in FIG. 5C, in a case where the cut-angle θ of the piezoelectric layer is about 30°, the phase of the third harmonic excitation signal exceeds about −45° when the duty D is equal to or more than about 0.5. That is, in a case where the cut-angle θ is about 30°, the unnecessary waves of the third harmonic excitation increase as the duty D increases.

However, increasing the duty D of the IDT electrode is effective as a method of increasing the electrostatic capacity of the acoustic wave resonator without increasing the size of the IDT electrode. In addition, since, by increasing the duty D, the line width of the electrode finger can be increased, it is possible to reduce or prevent the manufacturing variation of the IDT electrode.

From the above viewpoint, the inventor has found a combination of the duty D and the cut-angle θ at which unnecessary waves of third harmonic excitation can be reduced or prevented in a region where the duty D of the IDT electrode is more than 0.5.

Table 2, Table 3, and Table 4 show the phases of third harmonic excitation signals when the duty D and the cut-angle θ are changed. Specifically, Table 2 shows the phase of the third harmonic excitation when the duty D is equal to or more than about 0.5 and the cut-angle θ is about 0° to about 32.5°. Table 3 shows the phase of the third harmonic excitation when the duty D is equal to or more than about 0.5 and the cut-angle θ is about 32.5° to about 67.5°. Table 4 shows the phase of the third harmonic excitation when the duty D is equal to or more than about 0.5 and the cut-angle θ is about 67.5° to about 92.5°.

The numerical value a of the cut-angle shown in Tables 2 to 4 means that the cut-angle has a range of α±about 2.5°. The numerical value β of the duty D means that the duty has a range of β−about 0.012 to β+about 0.013.

In Tables 2 to 4, in the region where the duty D is more than about 0.5, a range in which the phase of the third harmonic excitation is smaller than the phase at (D, θ)=(0.5, 30) used in the related art is as follows (in a thick line frame, a double line frame, and a triple line frame in Tables 2 to 4): (1) about 0.513≤D≤ about 0.568 and about 2.5≤θ≤ about 17.5, (2) about 0.538≤D≤ about 0.568 and about 17.5≤θ≤ about 22.5, (3) about 0.538≤D≤ about 0.588 and about 42.5≤θ≤ about 52.5, (4) about 0.538≤D≤ about 0.613 and about 52.5≤θ≤ about 67.5, (5) about 0.513≤D≤ about 0.638 and about 67.5≤θ≤ about 77.5, and (6) about 0.513≤D≤ about 0.713 and about 77.5≤θ≤ about 92.5.

That is, the series arm resonator 11 (first acoustic wave resonator) of the filter 10 according to the present example embodiment satisfies any one of (1) to (6) described above.

Accordingly, it is possible to provide the filter 10 including the IDT electrode in the piston mode in which the generation of unnecessary waves of the third harmonic excitation is reduced or prevented in the region where the duty D is large, which is advantageous for the reduction in size and the reduction or prevention in manufacturing variation.

By applying the first acoustic wave resonator satisfying any one or more of (1) to (6) described above to the series arm resonator 11 connected closest to the common terminal 100 in the filter 10, it is possible to effectively reduce the return loss at the frequency of the third harmonic excitation in a case where the filter 10 is viewed from the common terminal 100. Thus, it is possible to reduce or prevent the deterioration of the bandpass characteristics of the filter 20 connected to the common terminal 100 at the frequency of the third harmonic excitation.

The first acoustic wave resonator satisfying any one or more of (1) to (6) described above does not need to be applied to the series arm resonator 11 and may be applied to at least one of the series arm resonators 12 to 14 and the parallel arm resonators 15 to 18 of the filter 10. Even in this case, it is possible to provide the filter 10 including the IDT electrode in the piston mode in which the generation of unnecessary waves of the third harmonic excitation is reduced or prevented in the region where the duty D is large, which is advantageous for the reduction in size and the reduction or prevention in the manufacturing variation.

It is preferable that the series arm resonator 11 (first acoustic wave resonator) of the filter 10 according to the present example embodiment satisfies either one of the followings (in a double line frame and a triple line frame in Table 3): (7) about 0.538≤D≤ about 0.588 and about 42.5≤θ≤ about 52.5, and (8) about 0.538≤D≤ about 0.613 and about 52.5≤θ≤ about 57.5.

In a region where the cut-angle θ is equal to or less than about 30°, the crystallinity of the IDT electrode 30 and the reflective electrode 40 provided on the piezoelectric layer 51 is decreased, and the electric power handling capability is decreased. In addition, in a region where the cut-angle θ is equal to or more than about 60°, the Rayleigh wave response occurring in a frequency region of approximately 0.75 times the fundamental wave is increased. Regarding this, by satisfying either (7) or (8) described above, it is possible to provide the filter 10 including the IDT electrode in the piston mode in which the generation of unnecessary waves of third harmonic excitation and Rayleigh waves is reduced or prevented while securing electric power handling capability, in the region where the duty D is large, which is advantageous for the reduction in size and the reduction or prevention in manufacturing variation.

In addition, it is preferable that the series arm resonator 11 (first acoustic wave resonator) of the filter 10 according to the present example embodiment satisfies (7) about 0.538≤D≤ about 0.588 and about 42.5≤θ≤ about 52.5 (in the triple line frame in Table 3).

In a region where the cut-angle θ is equal to or less than about 30°, the crystallinity of the IDT electrode 30 and the reflective electrode 40 provided on the piezoelectric layer 51 is decreased, and the electric power handling capability is decreased. In addition, as the cut-angle θ becomes more than about 55°, the Rayleigh wave response increases. Regarding this, by satisfying (7) described above, it is possible to provide the filter 10 including the IDT electrode in the piston mode in which the generation of unnecessary waves of third harmonic excitation and Rayleigh waves is more reduced or prevented while securing electric power handling capability, in the region where the duty D is large, which is advantageous for the reduction in size and the reduction or prevention in manufacturing variation.

### 5. Advantageous Effects and Like

As described above, the filter 10 according to the present example embodiment and the second modified example includes the first acoustic wave resonator including the piezoelectric substrate 50 and the IDT electrode 30 located at the piezoelectric substrate 50. The piezoelectric substrate 50 includes the piezoelectric layer 51 at which the IDT electrode 30 is provided, and the piezoelectric layer 51 made of lithium tantalate, the high acoustic velocity layer 53 in which the acoustic velocity of a bulk wave propagating in the high acoustic velocity layer 53 is higher than the acoustic velocity of an acoustic wave propagating in the piezoelectric layer 51, and the low acoustic velocity layer 52 in which the acoustic velocity of a bulk wave is lower than the acoustic velocity of a bulk wave propagating in the piezoelectric layer 51, the low acoustic velocity layer 52 being located between the piezoelectric layer 51 and the high acoustic velocity layer 53. The IDT electrode 30 includes the plurality of electrode fingers 31a and the plurality of electrode fingers 31b that are located in parallel or substantially in parallel with each other, the busbar electrode 32a configured to connect single ends of the plurality of electrode fingers 31a to each other, and the busbar electrode 32b configured to connect single ends of the plurality of electrode fingers 31b to each other, the busbar electrode 32b being located to oppose the busbar electrode 32a with the plurality of electrode fingers 31a and the plurality of electrode fingers 31b interposed between the busbar electrode 32b and the busbar electrode 32a. In a case where a region in which the plurality of electrode fingers 31a and the plurality of electrode fingers 31b overlap each other when viewed from the first direction that is parallel or substantially parallel to the piezoelectric layer 51 and is orthogonal to the extension direction of the electrode fingers 31a and the electrode fingers 31b is denoted by the intersection region W, the intersection region W includes the central region C located at the center in the extension direction and the edge region E that is located at both outer sides of the central region C in the extension direction and has the acoustic velocity lower than the acoustic velocity in the central region C. The IDT electrode 30 further includes the mass addition films 35a and 35b (36a and 36b) located in the second direction perpendicular or substantially perpendicular to the main surface of the piezoelectric layer 51 at at least one of the plurality of electrode fingers 31a and the plurality of electrode fingers 31b in the edge region E. In a case where the duty of the IDT electrode 30 is denoted by D, and the cut-angle of the piezoelectric layer 51 is denoted by θ°, any one or more of following expressions is satisfied: (1) about 0.513≤D≤ about 0.568 and about 2.5≤θ≤ about 17.5, (2) about 0.538≤D≤ about 0.568 and about 17.5≤θ≤ about 22.5, (3) about 0.538≤D≤ about 0.588 and about 42.5≤θ≤ about 52.5, (4) about 0.538≤D≤ about 0.613 and about 52.5≤θ≤ about 67.5, (5) about 0.513≤D≤ about 0.638 and about 67.5≤θ≤ about 77.5, and (6) about 0.513≤D≤ about 0.713 and about 77.5≤θ≤ about 92.5.

Accordingly, it is possible to provide the filter 10 including the IDT electrode 30 in the piston mode in which the generation of unnecessary waves of the third harmonic excitation is reduced or prevented in the region where the duty D is large, which is advantageous for the reduction in size and the reduction or prevention in manufacturing variation.

In addition, for example, in the filter 10, any one of (1) about 0.538≤D≤ about 0.588 and about 42.5≤θ≤ about 52.5, and (2) about 0.538≤D≤ about 0.613 and about 52.5≤θ≤ about 57.5 is also satisfied.

Accordingly, it is possible to provide the filter 10 including the IDT electrode in the piston mode in which the generation of unnecessary waves of third harmonic excitation and Rayleigh waves is reduced or prevented while securing electric power handling capability, in the region where the duty D is large, which is advantageous for the reduction in size and the reduction or prevention in manufacturing variation.

In addition, for example, in the filter 10, about 0.538≤D≤ about 0.588 and about 42.5≤θ≤about 52.5 are also satisfied.

Accordingly, in the filter 10, it is possible to provide the filter 10 including the IDT electrode in the piston mode in which the generation of unnecessary waves of third harmonic excitation and Rayleigh waves is more reduced or prevented while securing electric power handling capability, in the region where the duty D is large, which is advantageous for the reduction in size and the reduction or prevention in manufacturing variation.

In addition, for example, in the filter 10, the mass addition films 35a and 35b are located in the second direction of the plurality of electrode fingers 31a, the plurality of electrode fingers 31b, and the region between the plurality of electrode fingers 31a and the plurality of electrode fingers 31b in the edge region E.

Accordingly, it is possible to continuously form each of the mass addition films 35a and 35b over a plurality of electrode fingers in the edge region E, and thus, it is possible to improve the formation accuracy of the mass addition films 35a and 35b.

In addition, for example, in the filter 10, the mass addition films 35a and 35b include tantalum oxide.

Accordingly, even though the mass addition films 35a and 35b are provided in the region between the electrode fingers 31a and 31b, it is possible to reduce or prevent the ripples in the transverse mode without deteriorating the resonance characteristics of the first acoustic wave resonator.

In addition, for example, in the filter 10, the mass addition films 36a and 36b are located in the second direction of only at least one of the plurality of electrode fingers 31a or the plurality of electrode fingers 31b in the edge region E, and the mass addition films 36a and 36b are formed of the same conductive material as the plurality of electrode fingers 31a and the plurality of electrode fingers 31b.

Accordingly, since each of the mass addition films 36a and 36b can be formed by the same process as the electrode fingers 31a and 31b, it is possible to reduce or prevent the ripples in the transverse mode while the manufacturing process is simplified.

In addition, for example, in the filter 10, the duty D of the IDT electrode 30 is obtained by averaging the duties of the plurality of electrode fingers 31a and the plurality of electrode fingers 31b.

Accordingly, it is possible to define the duty D of the IDT electrode 30 even in a case where the duties of the plurality of electrode fingers 31a and the plurality of electrode fingers 31b are not uniform.

In addition, for example, the filter 10 includes the terminals 111 and 112 and a plurality of acoustic wave resonators including the first acoustic wave resonator. The plurality of acoustic wave resonators include the series arm resonators 11 to 14 that are located in series in a path connecting the terminals 111 and 112, and the parallel arm resonators 15 to 18 that are connected between the path and the ground.

Accordingly, in the ladder filter 10, it is possible to reduce or prevent the unnecessary waves of the third harmonic excitation.

In addition, for example, the filter 10A according to the first modified example includes a plurality of acoustic wave resonators including the first acoustic wave resonator, and the plurality of acoustic wave resonators include a longitudinally coupled resonator.

Accordingly, in the filter 10A including the longitudinally coupled resonator, it is possible to reduce or prevent the unnecessary waves of the third harmonic excitation.

In addition, for example, the multiplexer 1 according to the present example embodiment includes the common terminal 100, the filter 10 or 10A connected to the common terminal 100, and the filter 20 connected to the common terminal 100.

Accordingly, it is possible to provide the multiplexer 1 in which the unnecessary waves of the third harmonic excitation generated in the filter 10 are reduced or prevented.

In addition, for example, in the multiplexer 1, the filter 10 or 10A includes a plurality of acoustic wave resonators including the first acoustic wave resonator, and the first acoustic wave resonator is connected closest to the common terminal 100 among the plurality of acoustic wave resonators.

Accordingly, it is possible to effectively reduce the return loss at the frequency of the third harmonic excitation in a case where the filter 10 or 10A is viewed from the common terminal 100. Thus, it is possible to reduce or prevent the deterioration of the bandpass characteristics of the filter 20 connected to the common terminal 100 at the frequency of the third harmonic excitation.

Further, for example, in the multiplexer 1, the filter 20 has a pass band that is located on the higher frequency side than the pass band of the filter 10.

Accordingly, even though the unnecessary waves of the third harmonic excitation generated by the filter 10 are included in the vicinity of the pass band of the filter 20, it is possible to reduce or prevent the deterioration in the bandpass characteristic of the filter 20.

### Other Example Embodiments

Hitherto, acoustic wave devices and multiplexers according to the present invention have been described by describing example embodiments and modified examples. However, the present invention is not limited to the above-described example embodiments and modified examples. The present invention also includes modified examples obtained such that those skilled in the art modify the example embodiments and the modified examples in various manners within departing from the scope of the concept of the present invention, or various devices incorporating the acoustic wave device and the multiplexer according to the present invention.

In addition, for example, in the acoustic wave devices and the multiplexers according to example embodiments and modified examples, matching elements such as an inductor and a capacitor, and a switch circuit may be connected between respective constituent elements.

For example, the resonant frequency and the anti-resonant frequency described in the example embodiments and the modified examples are derived by bringing an RF probe into contact with two input/output electrodes of the acoustic wave resonator to measure reflection characteristics.

Example embodiments of the present invention can be widely used, for example, as a transmission and reception filter and a multiplexer used in the front end of a radio communication terminal that requires low loss in the pass band and high attenuation in the non-pass band.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a first acoustic wave resonator including a substrate and an interdigital transducer (IDT) electrode on the substrate;
wherein
the substrate includes:
a piezoelectric layer at which the IDT electrode is provided, the piezoelectric layer being made of lithium tantalate;
a high acoustic velocity layer in which an acoustic velocity of a bulk wave propagating in the high acoustic velocity layer is higher than an acoustic velocity of an acoustic wave propagating in the piezoelectric layer; and
a low acoustic velocity layer in which an acoustic velocity of a bulk wave is lower than an acoustic velocity of a bulk wave propagating in the piezoelectric layer, the low acoustic velocity layer being located between the piezoelectric layer and the high acoustic velocity layer;
the IDT electrode includes:
a plurality of first electrode fingers and a plurality of second electrode fingers located in parallel or substantially in parallel with each other;
a first busbar electrode connecting single ends of the plurality of first electrode fingers to each other; and
a second busbar electrode connecting single ends of the plurality of second electrode fingers to each other, the second busbar electrode being opposed to the first busbar electrode with the plurality of first electrode fingers and the plurality of second electrode fingers interposed between the second busbar electrode and the first busbar electrode;
where a region in which the plurality of first electrode fingers and the plurality of second electrode fingers overlap each other when viewed from a first direction that is parallel or substantially parallel to the piezoelectric layer and is orthogonal or substantially orthogonal to an extension direction of the first electrode fingers and the second electrode fingers is denoted by an intersection region, the intersection region includes a central region located at a center in the extension direction and an edge region that is located at both outer sides of the central region in the extension direction and has an acoustic velocity lower than an acoustic velocity in the central region;
the IDT electrode further includes:
a mass addition film located in a second direction perpendicular or substantially perpendicular to a main surface of the piezoelectric layer at at least one of the plurality of first electrode fingers and the plurality of second electrode fingers in the edge region; and
where a duty of the IDT electrode is denoted by D, and a cut-angle of the piezoelectric layer is denoted by θ°, any one or more of the following expressions is satisfied:
about 0.513≤D≤ about 0.568 and about 2.5≤θ≤ about 17.5; (1)
about 0.538≤D≤ about 0.568 and about 17.5≤θ≤ about 22.5; (2)
about 0.538≤D≤ about 0.588 and about 42.5≤θ≤ about 52.5; (3)
about 0.538≤D≤ about 0.613 and about 52.5≤θ≤ about 67.5; (4)
about 0.513≤D≤ about 0.638 and about 67.5≤θ≤ about 77.5; (5)
about 0.513≤D≤ about 0.713 and about 77.5≤θ≤ about 92.5. (6)

2. The acoustic wave device according to claim 1,
wherein either of the following expressions is also satisfied:
about 0.538≤D≤ about 0.588 and about 42.5≤θ≤ about 52.5; (1)
about 0.538≤D≤ about 0.613 and about 52.5≤θ≤ about 57.5. (2)

3. The acoustic wave device according to claim 2, wherein about 0.538≤D≤ about 0.588 and about 42.5≤θ≤ about 52.5 are also satisfied.

4. The acoustic wave device according to claim 1,
wherein the mass addition film is located in the second direction at the plurality of first electrode fingers, the plurality of second electrode fingers, and a region between the plurality of first electrode fingers and the plurality of second electrode fingers in the edge region.

5. The acoustic wave device according to claim 4,
wherein the mass addition film includes tantalum oxide.

6. The acoustic wave device according to claim 1, wherein
the mass addition film is located in the second direction at only at least one of the plurality of first electrode fingers and the plurality of second electrode fingers in the edge region; and
the mass addition film includes a same conductive material as the plurality of first electrode fingers and the plurality of second electrode fingers.

7. The acoustic wave device according to claim 1,
wherein the duty D of the IDT electrode is obtained by averaging duties of the plurality of first electrode fingers and the plurality of second electrode fingers.

8. The acoustic wave device according to claim 1, further comprising:
a first input/output terminal and a second input/output terminal; and
a plurality of acoustic wave resonators including the first acoustic wave resonator; wherein
the plurality of acoustic wave resonators include:
a series arm resonator located in series in a path connecting the first input/output terminal and the second input/output terminal; and
a parallel arm resonator connected between the path and ground.

9. The acoustic wave device according to claim 1, further comprising:
a plurality of acoustic wave resonators including the first acoustic wave resonator; wherein
the plurality of acoustic wave resonators include a longitudinally coupled resonator.

10. A multiplexer comprising:
a common terminal;
the acoustic wave device according to claim 1, which is connected to the common terminal; and
a filter connected to the common terminal.

11. The multiplexer according to claim 10, wherein
the acoustic wave device includes a plurality of acoustic wave resonators including the first acoustic wave resonator; and
the first acoustic wave resonator is connected closest to the common terminal among the plurality of acoustic wave resonators.

12. The multiplexer according to claim 10,
wherein the filter has a pass band that is located on a higher frequency side than a pass band of the acoustic wave device.

13. An acoustic wave device comprising:
a first acoustic wave resonator including a substrate and an interdigital transducer (IDT) electrode on the substrate;
wherein
the substrate includes:
a piezoelectric layer at which the IDT electrode is provided, the piezoelectric layer being made of lithium tantalate;
a high acoustic velocity layer including any one of silicon nitride, aluminum nitride, lithium tantalate, lithium niobate, crystal, alumina, sapphire, magnesia, silicon carbide, zirconia, cordierite, mullite, steatite, forsterite, diamond, glass, silicon, and gallium nitride, or a material including any one of silicon nitride, aluminum nitride, lithium tantalate, lithium niobate, crystal, alumina, sapphire, magnesia, silicon carbide, zirconia, cordierite, mullite, steatite, forsterite, diamond, glass, silicon, and gallium nitride as a main component; and
a low acoustic velocity layer including any one of silicon oxide, glass, silicon oxynitride, lithium oxide, and tantalum oxide, or a material including any one of silicon oxide, glass, silicon oxynitride, lithium oxide, and tantalum oxide as a main component, the low acoustic velocity layer being located between the piezoelectric layer and the high acoustic velocity layer;
the IDT electrode includes:
a plurality of first electrode fingers and a plurality of second electrode fingers that are located in parallel or substantially in parallel to each other;
a first busbar electrode connecting single ends of the plurality of first electrode fingers to each other; and
a second busbar electrode connecting single ends of the plurality of second electrode fingers to each other, the second busbar electrode being located to oppose the first busbar electrode with the plurality of first electrode fingers and the plurality of second electrode fingers interposed between the second busbar electrode and the first busbar electrode;
where a region in which the plurality of first electrode fingers and the plurality of second electrode fingers overlap each other when viewed from a first direction that is parallel or substantially parallel to the piezoelectric layer and is orthogonal or substantially orthogonal to an extension direction of the first electrode fingers and the second electrode fingers is denoted by an intersection region, the intersection region includes a central region located at a center in the extension direction and an edge region that is located at both outer sides of the central region in the extension direction and has an acoustic velocity lower than an acoustic velocity in the central region;
the IDT electrode further includes:
a mass addition film located in a second direction perpendicular or substantially perpendicular to a main surface of the piezoelectric layer at at least one of the plurality of first electrode fingers and the plurality of second electrode fingers in the edge region; and
where a duty of the IDT electrode is denoted by D, and a cut-angle of the piezoelectric layer is denoted by θ°, at least any one of the following expressions is satisfied:
about 0.513≤D≤ about 0.568 and about 2.5≤θ≤ about 17.5; (1)
about 0.538≤D≤ about 0.568 and about 17.5≤θ≤ about 22.5; (2)
about 0.538≤D≤ about 0.588 and about 42.5≤θ≤ about 52.5; (3)
about 0.538≤D≤ about 0.613 and about 52.5≤θ≤ about 67.5; (4)
about 0.513≤D≤ about 0.638 and about 67.5≤θ≤ about 77.5; (5)
about 0.513≤D≤ about 0.713 and about 77.5≤θ≤ about 92.5. (6)

14. The multiplexer according to claim 12, wherein
the pass band of the filter includes at least one of an uplink operation band and a downlink operation band of a first band; and
the pass band of the acoustic wave device includes at least one of an uplink operation band and a downlink operation band of a second band different from the first band.

15. The acoustic wave device according to claim 1, further comprising:
a protection layer covering the plurality of first electrode fingers and the plurality of second electrode fingers; wherein
the protection layer is made from a dielectric film containing silicon oxide as a main component.
